(19) United States
(12) Patent Application Publication
(10) Pub. No.: US 2024/0103371 A1
(43) Pub. Date: Mar. 28, 2024

(54) PHOTO TREATMENT DEVICE

(71) Applicant: Ushio Denki Kabushiki Kaisha, Chiyoda-ku, Tokyo, (JP)

(72) Inventor: Akihiro Shimamoto, Tokyo (JP)

(73) Assignee: Ushio Denki Kabushiki Kaisha, Chiyoda-ku, Tokyo, (JP)

(21) Appl. No.: 18/271,038

(22) PCT Filed: Jan. 26, 2022
(86) PCT No.: PCT/JP2022/002800

§ 371 Date: Jul. 5, 2023

(30) Foreign Application Priority Data
Feb. 8, 2021 (JP) 2021-017930

(51) Int. Cl. G03F 7/16; G03F 7/00; G03F 7/004

(52) U.S. Cl. CPC G03F 7/167; G03F 7/0045; G03F 7/70875; G03F 7/70933

(57) ABSTRACT

A photo treatment device includes a gas generator that generates a mixed gas in which a raw material gas containing an organic compound having at least one of oxygen atoms and nitrogen atoms is mixed with a carrier gas at a desired mixing ratio; a chamber connected to the gas generator for allowing ventilation so as to enable the mixed gas to be supplied thereinside and that is capable of placing the workpiece thereinside; and a light source that irradiates the raw material gas with ultraviolet light having intensity at least in a wavelength band of 205 nm or less. The surface of the workpiece is modified with the raw material gas that has been irradiated with the ultraviolet light.

### TECHNICAL FIELD

The present invention relates to a photo treatment device that modifies a surface of a workpiece.

### BACKGROUND ART

A method of modifying the surface of a workpiece by using vacuum ultraviolet light to activate a specific raw material gas to generate radicals and then supplying the radicals to the workpiece has been known in the past.

For example, Patent Document 1 describes a method of removing smear (residue) by using vacuum ultraviolet light to activate a humidified gas to generate hydroxyl radicals and then supplying the generated hydroxyl radicals to a workpiece. In addition, Patent Document 2 describes a method of ashing or removing organic matter from the surface of a workpiece by using vacuum ultraviolet light to activate ammonia gas to generate radicals and supplying the generated radicals to the workpiece.

### CITATION LIST

Patent Document 1: JP-A-2016-004802

Patent Document 2: JP-A-2005-158796

### SUMMARY OF INVENTION

### Technical Problem

As a result of diligent research, the present inventor has acquired the knowledge that an organic compound containing at least one of oxygen atoms and nitrogen atoms as a raw material gas is activated by ultraviolet light to generate radicals, which exert a specific modification effect on a workpiece. Accordingly, the present inventor has devised a method of activating an organic compound containing oxygen atoms as a raw material gas with vacuum ultraviolet light to generate radicals, and then modifying the surface of a workpiece with these radicals.

An object of the present invention is to embody a device based on the above idea. In other words, it is an object of the present invention to provide a photo treatment device that supplies a workpiece with radicals formed by activating an organic compound containing oxygen atoms or nitrogen atoms as a raw material gas using ultraviolet light and modifying the surface of the workpiece.

In the course of examining such a photo treatment device, the present inventor noticed the importance of controlling the concentration of a raw material gas when using an organic compound as a raw material gas. If the concentration of a raw material gas is too low, the amount of radicals that react with the surface of the workpiece is reduced, and the workpiece is treated inefficiently. If the concentration of a raw material gas is too high, the vacuum ultraviolet light is absorbed by the raw material gas before it reaches the surface of the workpiece, preventing the generation of radicals in the vicinity of the surface of the workpiece. As a result, the number of radicals that react with the surface of the work piece is reduced, and the workpiece is treated inefficiently. Furthermore, since the raw material gas contains an organic compound containing at least one of oxygen atoms and nitrogen atoms, a high concentration of the raw material gas may cause abnormal combustion, such as explosion. From the viewpoint of preventing abnormal combustion, the concentration of the raw material gas is necessary to be controlled. The prevention of abnormal combustion is a new technical matter that need not be considered in the case of the conventional technologies described above.

A photo treatment device of the present invention includes a gas generator that generates a mixed gas in which a raw material gas containing an organic compound having at least one of oxygen atoms and nitrogen atoms is mixed with a carrier gas at a desired mixing ratio, a chamber connected to the gas generator for allowing ventilation so as to enable the mixed gas to be supplied thereinside and that is capable of placing the workpiece thereinside, a light source that irradiates the raw material gas with ultraviolet light having intensity at least in a wavelength band of 205 nm or less. The surface of the workpiece is modified with the raw material gas that has been irradiated with the ultraviolet light. The irradiation of the raw material gas with ultraviolet light having intensity in a wavelength band of at least 205 nm or less generates the radicals of the raw material gas. These radicals modify the surface of the workpiece. Since the present invention uses a gas generator that mixes a raw material gas with a carrier gas at a desired mixing ratio, the concentration of the raw material gas in the mixed gas can be regulated to an appropriate range. This enables the surface of the workpiece to be modified with high efficiency and also prevents the occurrence of abnormal combustion of the mixed gas. The carrier gas is used to transport the raw material gas to the chamber. As the carrier gas, low-activity gas species that contribute to no surface modification of the workpiece are used. Examples of carrier gas include an inert gas such as nitrogen gas or argon gas.

The gas generator may include a container that stores an organic solvent containing the organic compound having oxygen atoms, a carrier gas supply pipe that supplies the carrier gas to the organic solvent stored in the container, and a mixed gas supply pipe that feeds the mixed gas into the chamber. The mixed gas may be generated by supplying the carrier gas to the organic solvent. This is a method of generating a raw material gas by the bubbling method. With this method, the mixing ratio of the raw material gas to the carrier gas can be set to a desired value by regulating the concentration or liquid volume of the organic solvent or the supply volume of the carrier gas. Thus, the concentration of the raw material gas in the mixed gas can be regulated to an appropriate range.

The gas generator may include a heater that heats at least one of the container and the carrier gas. This heater, which can heat at least one of the organic solvent and the carrier gas, enables a large amount of the organic solvent to be volatilized. As a result, the concentration of the raw material gas can be increased. Accordingly, this heater serves as one means for regulating the concentration of the raw material gas in the mixed gas to an appropriate range.

The gas generator may include a vaporizer that introduces an organic solvent containing the organic compound into a vaporization compartment to vaporize it, a carrier gas supply pipe connected to the vaporizer and that supplies the carrier gas, and a mixed gas supply pipe that delivers the mixed gas to the chamber. The mixed gas may be generated by supplying the carrier gas to the organic solvent.

The mixed gas supply pipe may be connected to a dilution gas supply pipe that dilutes the mixed gas. As a dilution gas, a low-activity gas species that does not contribute to the modification of the surface of the workpiece is used, as is similar to the carrier gas. Examples of the dilution gas include an inert gas such as nitrogen gas or argon gas. Diluting the mixed gas with the dilution gas makes it possible to reduce the concentration of the raw material gas in the mixed gas after the dilution. As a result, the concentration of the raw material gas can be reduced. Accordingly, the supply of the dilution gas from the dilution gas supply pipe serves as one means for regulating the concentration of the raw material gas in the mixed gas to an appropriate range.

The photo treatment device may include a cooler disposed between the gas generator and the chamber and that cools the mixed gas. Cooling the mixed gas lowers the saturated vapor amount of the mixed gas and condenses some of the vaporized organic solvent. This reduces the amount of the raw material gas contained in the mixed gas. Accordingly, the cooler serves as one means for regulating the concentration of the raw material gas in the mixed gas to an appropriate range.

The photo treatment device may include a raw material gas concentration detector that detects the concentration of the raw material gas in the mixed gas, and at least one of the supply volume of the carrier gas and the supply volume of the dilution gas may be regulated based on a detection result of the raw material gas concentration detector. This makes it possible to regulate the concentration of the raw material gas in the mixed gas to a more appropriate range.

The photo treatment device may also include a supplementary fluid supply pipe that supplies a fluid containing an auxiliary raw material that facilitates the modification of the workpiece by radicalization may.

The supplementary fluid supply pipe may be connected to the mixed gas supply pipe for allowing ventilation.

The supplementary fluid supply pipe may be connected to the chamber for allowing ventilation at a position different from that at which the mixed gas supply pipe is connected to the chamber for allowing ventilation. Avoiding mixing the raw material gas with the fluid containing the auxiliary raw material makes it possible to prevent reactions such as combustion.

An auxiliary raw material that facilitates the modification of the workpiece may be added to the organic solvent stored in the container. The raw material gas and the auxiliary raw material gas or atomized liquid can be produced simultaneously.

The photo treatment device may include a second chamber that is partitioned from the chamber, and capable of placing the workpiece thereinside and supplying a fluid containing an auxiliary raw material that facilitates the modification of the workpiece thereinside, and a light source that irradiates the fluid containing the auxiliary raw material with ultraviolet light having intensity in a wavelength band of at least 205 nm or less. Avoiding mixing the raw material gas with the fluid containing the auxiliary raw material prevents reactions such as combustion.

Incidentally, there may be a case in which the photo treatment device does not have a mixed gas generator, and the mixed gas is supplied from outside the photo treatment device. In such a case, it is recommended that the photo treatment device have a concentration detector so as to check whether or not the concentration of the raw material gas in the mixed gas that is supplied is in a desired concentration range. That is, the photo treatment device of the present invention includes a chamber to which a mixed gas including a raw material gas containing an organic compound having at least one of oxygen atoms and nitrogen atoms and a carrier gas is supplied, and that is capable of placing a workpiece thereinside, a light source that irradiates the raw material gas with ultraviolet light having intensity in a wavelength band of at least 205 nm or less, a raw material gas concentration detector that detects the concentration of the raw material gas in the mixed gas. The surface of the workpiece is modified with the raw material gas that has been irradiated with the ultraviolet light. This makes it possible to regulate a mixing ratio of the raw material gas to the carrier gas in the mixed gas to be supplied to the photo treatment device based on the detection result of the concentration of the raw material gas in the mixed gas. If the mixing ratio fails to be in a desired concentration range even after regulating the mixing ratio of the raw material gas to the carrier gas, the photo treatment device can be automatically stopped or an error signal can be issued.

The raw material gas concentration detector may be disposed to detect the mixed gas before the mixed gas enters the chamber. Details will be described below; however, this prevents the false detection of the raw material gas concentration detector due to the alteration products of organic solvent gases generated by light irradiation.

The chamber may include a temperature regulator that regulates the temperature of the workpiece. The temperature regulator is, for example, a device that can raise the temperature of the workpiece by electrical energy, heated fluid, or light energy, or cool the workpiece by electrical energy or cooling fluid. Using a temperature regulator makes it possible to control the progress of chemical reactions on the surface of the workpiece.

The light source may be located outside the chamber, and the ultraviolet light may be transmitted through the enclosure of the chamber and an atmospheric gas that are located between the light source and the chamber. Typically, a high voltage is applied to the light source to generate a discharge phenomenon. Hence, the light source may become a starting point of combustion, i.e., a source of fire. Disposing the light source outside the chamber further reduces the risk of abnormal combustion of raw material gas. In addition, disposing the light source outside the chamber prevents alteration products of the raw material gas from adhering to the surface of the light source, thereby preventing a decrease in the illuminance of the light source. Furthermore, the chamber can be made smaller, and also maintenance, inspection, or replacement of the light source can be simplified. Since the space between the light source and the chamber has a gas atmosphere that allows the ultraviolet light to transmit, the ultraviolet light is hardly attenuated outside the chamber.

The light source may be housed in a cylinder body, at least a part of the cylinder body may allow the ultraviolet light to transmit, and the space between the light source and the cylinder body may have an inert gas atmosphere. By housing the light source in the cylinder body and making the inside of the cylinder body have an inert gas atmosphere, the risk of abnormal combustion of raw material gas can be further reduced. In addition, housing the light source in the cylinder body prevents alteration products of the raw material gas from adhering to the surface of the light source, thereby preventing a decrease in the illuminance of the light source. Since the raw material gas used for the reaction of the workpiece is the raw material gas that exists in the vicinity of the workpiece, an inert gas atmosphere in the space between the light source and the cylinder body, which is in the vicinity of the light source, has little effect on the reaction with the workpiece. Rather, having the space between the light source and the cylinder body has an inert gas atmosphere suppresses the attenuation of the ultraviolet light, thus more of the ultraviolet light can be radiated to the raw material gas in the vicinity of the workpiece.

The photo treatment device may include an oxygen concentration detector that detects the concentration of oxygen contained in a gas discharged from the chamber. This confirms that the atmosphere has been discharged from the chamber and that the risk of abnormal combustion has been decreased.

The chamber may include at least one gas supply port through which the mixed gas is supplied thereinside and at least one gas discharge port through which the gas inside the chamber is discharged, and the caliber of the at least one gas discharge port among the at least one gas discharge port may be larger than the caliber of the at least one gas supply port among the at least one gas supply port. This enables the gas exhaust capacity to be larger than the gas supply capacity. As a result, the turbulence of mixed gas in the chamber associated with an insufficient exhaust and gas leakage from anywhere other than the gas discharge port to the outside of the chamber can be suppressed.

The chamber may include a gas supply port through which the mixed gas is supplied thereinside, a gas discharge port through which the gas inside the chamber is discharged, and a table on which the workpiece is placed and that is capable of lifting and lowering, and the table may include at least one gas jetting nozzle connected to the gas supply port for allowing ventilation, and at least one gas recovery nozzle connected to the gas discharge port for allowing ventilation. Providing the gas jetting nozzle and the gas recovery nozzle suppresses changes in the flow of the mixed gas even if the height of the lifting mechanism changes.

The table may have side walls surrounding the table, and a seal material may be disposed on the upper part of the side walls. An enclosed treatment space may be formed in the chamber by allowing the seal material to be in contact with the ceiling of the chamber. This decreases the supply volume of the mixed gas.

The total area of the nozzle cross-section of the gas recovery nozzle may be larger than the total area of the cross-section of the gas jetting nozzle. This enables the gas exhaust capacity to be larger than the gas supply capacity.

The photo treatment device may include an auxiliary plate having an inner side face that is in contact with the outer periphery of the workpiece and a front face that is substantially flush with the surface to be treated of the workpiece. This prevents the flow of the supplied mixed gas from being disturbed by bringing it into contact with the side face of the workpiece.

### Effects of the Invention

Accordingly, the present invention is capable of providing a device that supplies a workpiece with radicals formed by activating an organic compound containing oxygen atoms as a raw material gas using vacuum ultraviolet light and that modifies the surface of the workpiece.

### BRIEF DESCRIPTION OF DRAWINGS

FIG. 1 is an appearance view of a photo treatment device of a first embodiment.

FIG. 2A is a schematic view of the photo treatment device of the first embodiment in a non-treatment state.

FIG. 2B is a schematic view of the photo treatment device of the first embodiment in a treatment state.

FIG. 3A is a cross-sectional view schematically illustrating the surface modification of a fluororesin.

FIG. 3B is a cross-sectional view schematically illustrating the surface modification of a fluororesin.

FIG. 3C is a cross-sectional view schematically illustrating the surface modification of a fluororesin.

FIG. 3D is a cross-sectional view schematically illustrating the surface modification of a fluororesin.

FIG. 4A is a cross-sectional view schematically illustrating the surface modification of a metal oxide layer.

FIG. 4B is a cross-sectional view schematically illustrating the surface modification of a metal oxide layer.

FIG. 5 is an enlarged view of FIG. 2B.

FIG. 6 is a view illustrating an auxiliary plate.

FIG. 7 is a schematic view of a photo treatment device of a second embodiment.

FIG. 8 is a schematic view of a photo treatment device of a third embodiment.

FIG. 9 is a schematic view of a photo treatment device of a fourth embodiment.

FIG. 10 is a schematic view of a photo treatment device of a fifth embodiment.

FIG. 11 is a schematic view of a photo treatment device of a sixth embodiment.

FIG. 12 is a schematic view of a photo treatment device of a seventh embodiment.

FIG. 13A is a schematic view illustrating a photo treatment device of an eighth embodiment.

FIG. 13B is a schematic view illustrating a photo treatment device of a first variation example of the eighth embodiment.

FIG. 13C is a schematic view illustrating a photo treatment device of a second variation example of the eighth embodiment.

FIG. 14 is a schematic view of a photo treatment device of a ninth embodiment.

FIG. 15 is a schematic view of a photo treatment device of a tenth embodiment.

FIG. 16A is a schematic view illustrating a variation example of a chamber and a light source.

FIG. 16B is a schematic view illustrating a variation example of the chamber and the light source.

### DESCRIPTION OF EMBODIMENTS

Hereinafter, the embodiment of the present invention will be described with reference to the drawings. Each drawing disclosed herein is only schematically illustrated. In other words, the dimensional ratios in the drawings do not necessarily match the actual dimensional ratios, and the dimensional ratios among the drawings do not necessarily match each other.

### First Embodiment

### Overview of Photo Treatment Device

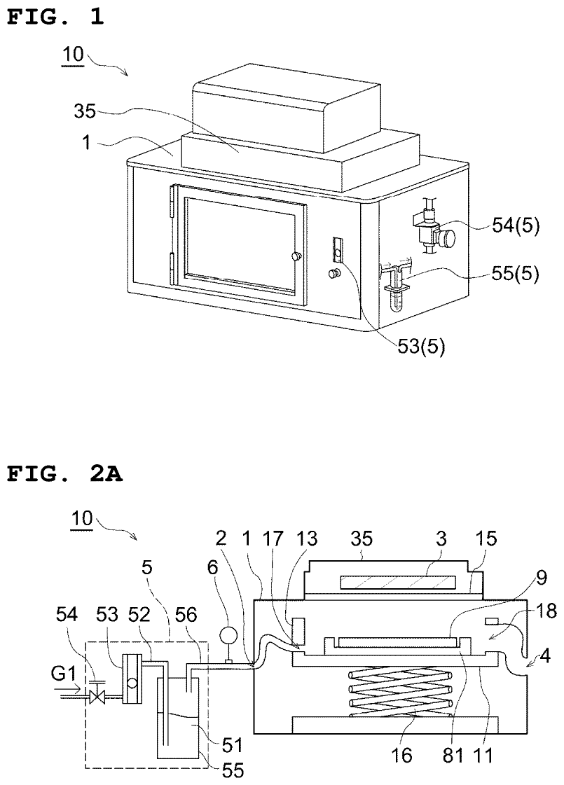

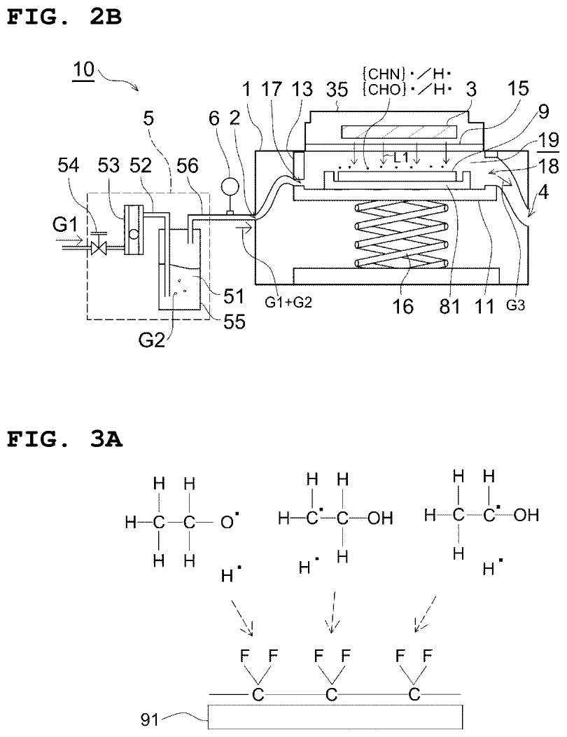

First, an overview of one embodiment of a photo treatment device will be described with reference to FIGS. 1, 2A, and 2B. FIG. 1 is an appearance view of a photo treatment device. FIGS. 2A and 2B are each a schematic view of the photo treatment device of FIG. 1. A photo treatment device 10 includes a chamber 1, a gas generator 5, and a light source 3. The appearance view of FIG. 1 illustrates that the chamber 1, a part constituting the gas generator 5, and a light source chamber 35 in which the light source 3 is disposed.

FIG. 2A illustrates the photo treatment device in the non-processing state, whereas FIG. 2B illustrates the photo treatment device in the treatment state. FIG. 2A will be discussed below. Referring to FIG. 2B, the gas generator 5 mixes a raw material gas G2 containing an organic compound having at least one of oxygen atoms and nitrogen atoms with a carrier gas G1 in a desired mixing ratio to produce a mixed gas (G1+G2). The carrier gas G1 is mainly an inert gas such as nitrogen gas or a noble gas, for example. The gas generator 5 is connected to the chamber 1 via a mixed gas supply pipe 56 for allowing ventilation, and the generated mixed gas (G1+G2) is supplied to the inside of the chamber 1 through the mixed gas supply pipe 56. Details of the gas generator 5 and the mixed gas (G1+G2) will be described below.

The chamber 1 includes a gas supply port 2 and a gas discharge port 4 in its enclosure. The chamber 1 has an internal space in which a workpiece 9 can be placed. In the present embodiment, the workpiece 9 is placed on an auxiliary plate 81. The auxiliary plate 81 is placed on a table 11. The table 11 is disposed in the chamber 1. The structure of the chamber 1 and the auxiliary plate 81 will be described below.

The light source chamber 35 in which the light source 3 is disposed is located outside the chamber 1. Of the enclosure of the chamber 1, the portion of an enclosure 15 located between the light source 3 and the chamber 1 is made of a material that transmits ultraviolet light L1 (e.g., quartz glass). As a result, the ultraviolet light L1 emitted from the light source 3 is radiated to the raw material gas G2 contained in the mixed gas (G1+G2) in the vicinity of the workpiece 9 in the chamber 1. In FIGS. 2A and 2B, the enclosure 15 transmitting the ultraviolet light L1 is located on the ceiling of the chamber 1; however, the enclosure 15 transmitting the ultraviolet light L1 may be located on the side wall of the chamber 1.

The light emitted by the light source 3 is vacuum ultraviolet light, more specifically, ultraviolet light having intensity at least in a wavelength band of 205 nm or less. The ultraviolet light L1 radiated to the raw material gas G2 activates the raw material gas G2 to generate radicals. Details of the radicals will be described below. The generated radicals modify the surface of the workpiece 9.

As used herein, “ultraviolet light having intensity in a wavelength band of at least 205 nm or less” means light having an emission band of 205 nm or less, and such light includes, for example, light having an emission spectrum in which the peak emission wavelength indicating the maximum intensity in broad wavelength light is 205 nm or less, and light having an emission spectrum in which one of the peaks is included in a wavelength band of 205 nm or less when the emission spectrum has multiple local maximum intensities (multiple peaks). Light having a wavelength band of 205 nm or less indicating at least 30% or more integrated intensity with respect to the total integrated intensity in the emission spectrum is also included in “ultraviolet light having intensity in a wavelength band of at least 205 nm or less”. Hereinafter, “ultraviolet light having intensity in a wavelength band of at least 205 nm or less” may be simply described as “ultraviolet light”.

For example, a xenon excimer lamp is used as the light source 3. A xenon excimer lamp has a peak emission wavelength of 172 nm, which is easily absorbed by an organic compound containing oxygen, generates many radicals, and is less likely to be absorbed by an inert gas.

Examples of the workpiece 9 include fluororesins used in various applications such as medical and high-frequency substrates, and printed wiring boards with metal oxide layers on their surface. The surface modification action differs depending on the type of the workpiece 9. Details will be described later, but when the surface of the workpiece 9 is fluororesins, the surface of fluororesins can be converted from hydrophobicity to hydrophilicity by surface modification. This, for example, increases bonding strength between the fluororesins and other materials. When the workpiece 9 is a printed wiring board with a metal oxide layer on its surface, the metal oxide layer can be reduced by surface modification. This increases the conductivity of the wiring section of printed wiring boards and improves the bonding strength of solder.

Radical Generation from Raw Material Gas by the Photo Treatment Device

Hereinafter, the mechanism of radical generation from the raw material gas G2 by the photo treatment device will be described. Here, ethanol (C₂H₅OH) is taken as the raw material gas G2, which is an organic compound containing oxygen atoms. The process of generating radicals by irradiating the molecules of ethanol with ultraviolet light (hν) is described while presenting the chemical reaction formula.

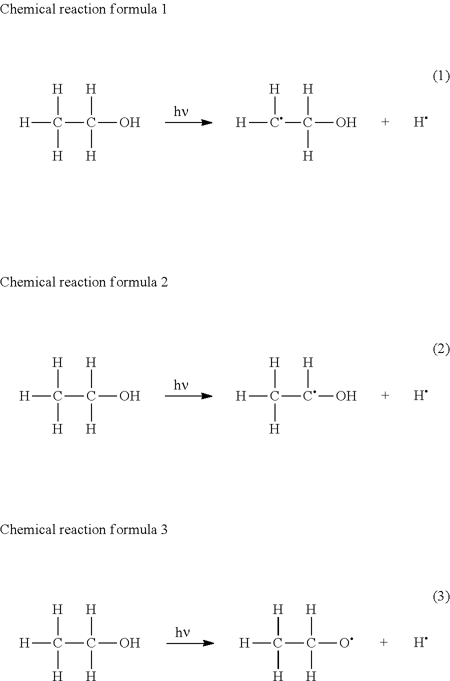

As shown in Formulas (1) to (3) above, when ultraviolet light (hν) is radiated onto an ethanol molecule, the energy of the ultraviolet light breaks the bonds between the atoms constituting the ethanol molecule, producing radicals consisting of carbon atoms, hydrogen atoms, and oxygen atoms (sometimes referred to as “{CHO} radicals” or “{CHO}”) and hydrogen radicals (sometimes denoted as “H·”). A radical is an atom or molecule with an unpaired electron. The {CHO} radicals include those in which C is radicalized and those in which O is radicalized. The three types of {CHO} radicals shown in Formula (1)-(3) above are formed depending on the difference in that which of C or O is radicalized and which position of C is radicalized. The {CHO} radicals may not be formed in equal proportions.

The three types of chemical reaction formulas shown in Formula (1) to (3) above represent {CHO} radicals having one atom with an unpaired electron. {CHO} radicals having two or more atoms with unpaired electrons may be generated by the irradiation of ultraviolet light.

Next, the case of organic compounds containing nitrogen atoms is described. As an example of organic compounds containing nitrogen atoms, ethylamine (C₂H₅NH₂) is taken. The chemical reaction formula for the process of irradiating ethylamine molecules with ultraviolet light (hν) to generate radicals is shown below.

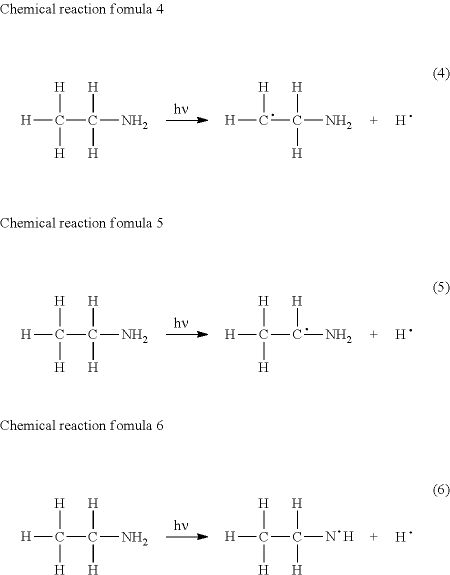

As shown in Formulas (4) to (6) above, when ultraviolet light (hν) is radiated to an ethylamine molecule, the energy of the ultraviolet light breaks the bonds between the atoms constituting the ethylamine molecule, producing radicals consisting of carbon atoms, hydrogen atoms, and nitrogen atoms (sometimes referred to as “{CHN} radicals”) and hydrogen radicals. A radical is an atom or molecule with an unpaired electron. The {CHN} radicals include those in which C is radicalized and those in which N is radicalized. The three types of {CHN} radicals shown in Formula (4)-(6) above are formed depending on the difference in that which of C or N is radicalized and which position of C is radicalized. The {CHN} radicals may not be formed in equal proportions.

The three chemical reaction formulas shown in Formulas (4) to (6) above represent {CHN} radicals having one atom with an unpaired electron. {CHN} radicals having two or more atoms with unpaired electrons can be generated by the irradiation of ultraviolet light.

As organic compounds in the raw material gas G2, examples with oxygen atoms in the chemical structure and examples with nitrogen atoms in the chemical structure were given; however, it is also possible to have both oxygen atoms and nitrogen atoms in the chemical structure.

The reaction to generate radicals by irradiating mixed gas with ultraviolet light proceeds independent of pressure, hence the inside of the chamber, which is the reaction site, is not necessarily a reduced pressure environment. However, in order to replace the atmosphere in the chamber 1 with a mixed gas atmosphere in a short time, a vacuum pump may be connected to the gas discharge port 4 to reduce the pressure inside the chamber 1.

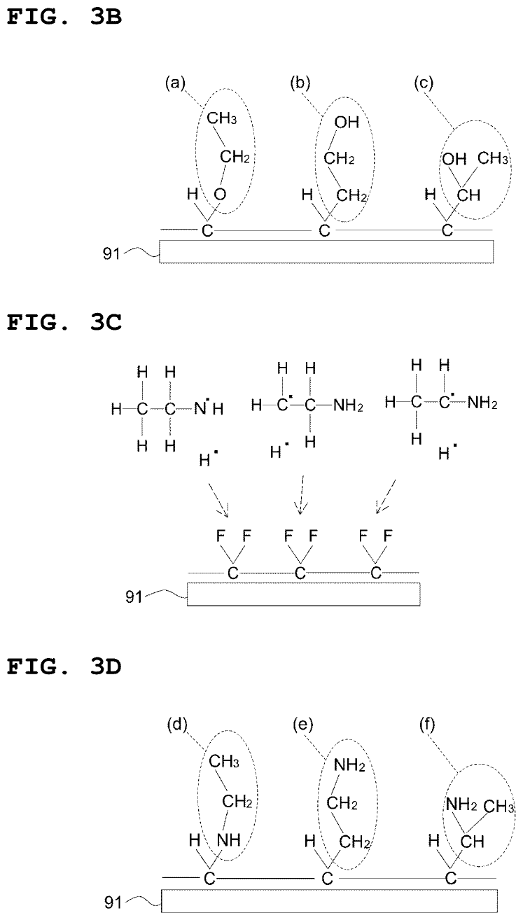

Hereinafter, the process of surface modification of the workpiece by the generated radicals will be described. The mechanism of surface modification depends on the material of the workpiece 9. First, with reference to FIGS. 3A and 3B, the surface modification in the case where the workpiece 9 is made of fluororesins is described. An example is shown where ethanol is used as the raw material gas G2. FIG. 3A is a cross-sectional view of a fluororesin 91 schematically illustrating a state in which the fluororesin 91 (in this case, PTFE) is just about to be subjected to surface modification. FIG. 3B is a cross-sectional view of the fluororesin 91 schematically illustrating a state in which the fluororesin 91 in FIG. 3A has been subjected to surface modification. FIGS. 3A and 3B are illustrated in a manner that the chemical structure of the surface of the fluororesin 91 can be understood.

As shown in FIG. 3A, there exist many fluorine atoms (F) bonded to carbon atoms (C) on the surface of the fluororesin 91 prior to surface modification. In addition, ethanol molecules are radicalized by absorbing ultraviolet light. There exist {CHO} radicals generated from ethanol molecules and hydrogen radicals in the vicinity of the surface of the fluororesin 91.

Fluorine atoms contained in the fluororesin 91 are in a state of bonding to carbon atoms. The bonding energy between a carbon atom and a fluorine atom is as high as 485 kJ/mol, requiring a very large amount of energy to separate a fluorine atom from a carbon atom by heat or light.

Here, a fluorine atom has an electronegativity of 4.0 and a hydrogen atom has an electronegativity of 2.2, which are very different from each other. Hence, a hydrogen radical can approach a fluorine atom by electrostatic attraction, forming a hydrogen fluoride (HF), which breaks the bond between the fluorine atom and the carbon atom. The HF formation reaction proceeds irreversibly because the bonding energy between a hydrogen atom and a fluorine atom is 568 kJ/mol, which is higher than that between a carbon atom and a fluorine atom, and HF leaves the surface of fluororesin as a gas. {CHO} radicals or hydrogen radicals are bound to the surface of the fluororesin 91 from which fluorine atoms have been pulled out. FIG. 3B illustrates a state after the bonding.

FIG. 3B illustrates a state in which six fluorine atoms have been pulled out, hydrogen radicals are bonded at three of the locations, and {CHO} radicals are bonded at the remaining three locations; however, fluorine atoms may remain on the surface. The number of bonds of hydrogen radicals may not be the same as the number of bonds of {CHO} radicals. For example, {CHO} radicals may be bonded to all the locations where fluorine atoms have been pulled out. On at least part of the surface of the fluororesin 91, there exist functional groups constituted by carbon atoms, hydrogen atoms, and oxygen atoms (hereinafter referred to as “{CHO} functional group”).

The {CHO} functional group shown as (a) in FIG. 3B is formed by bonding the {CHO} radical that has been obtained by Formula (3) above to the fluororesin 91. The {CHO} functional group shown as (b) in FIG. 3B is formed by bonding the {CHO} radical that has been obtained by Formula (1) above to the fluororesin 91. The {CHO} functional group shown as (c) in FIG. 3B is formed by bonding the {CHO} radical that has been obtained by Formula (2) above to the fluororesin 91.

The {CHO} functional group that has been bonded to the fluororesin 91 has polarity because it contains an oxygen atom. The {CHO} functional groups shown as (b) and (c) in FIG. 3B, each includes a hydroxy group at the end thereof, thus exhibiting strong hydrophilicity. The {CHO} functional group shown as (a) in FIG. 3B forms an ether bond with the fluororesin 91, thus exhibiting a certain hydrophilicity, although not as strong as that of a hydroxy group. In this way, hydrogen radicals and {CHO} radicals form a hydrophilic layer on the surface of the fluororesin 91. Therefore, when the workpiece 9 is fluororesin, the surface of fluororesin can be effectively hydrophilized by supplying radicals formed by activating an organic compound containing oxygen atoms. The {CHO} functional groups are also used for further hydrophilization by auxiliary raw materials that facilitate modification, which will be described in detail in the eighth embodiment.

Next, with reference to FIGS. 3C and 3D, an example is shown where the workpiece 9 is made of fluororesin and ethylamine is used as the raw material gas G2. FIG. 3C is a cross-sectional view schematically illustrating a state in which the fluororesin 91 (in this case, PTFE) is just about to be subjected to surface modification. FIG. 3D is a cross-sectional view schematically illustrating a state in which the fluororesin 91 of FIG. 3C has been subjected to surface modification. FIGS. 3C and 3D are illustrated in a manner that the chemical structure of the surface of the fluororesin 91 can be understood.

As shown in FIG. 3C, there exist many fluorine atoms (F) bonded to carbon atoms (c) on the surface of the fluororesin 91 prior to surface modification. In addition, ethylamine molecules are radicalized by absorbing ultraviolet light. There exist {CHN} radicals generated from ethylamine molecules and hydrogen radicals in the vicinity of the fluororesin 91.

FIG. 3D illustrates a state in which six fluorine atoms have been pulled out, hydrogen radicals are bonded at three of the locations and {CHN} radicals are bonded at the remaining three locations. Accordingly, on at least part of the surface of the fluororesin 91, there exist functional groups constituted by carbon atoms, hydrogen atoms, and oxygen atoms (hereinafter referred to as “{CHN} functional group”).

The {CHN} functional group shown as (d) in FIG. 3D is formed by bonding the {CHN} radical that has been obtained by Formula (6) above to the fluororesin 91. The {CHN} functional group shown as (e) in FIG. 3D is formed by bonding the {CHN} radical that has been obtained by Formula (4) above to the fluororesin 91. The {CHN} functional group shown as (f) in FIG. 3D is formed by bonding the {CHN} radical that has been obtained by Formula (5) above to the fluororesin 91. The surface on which the {CHN} functional groups shown as (d), (e), and (f) has been formed exhibits more hydrophilicity than the surface of the fluororesin 91. The {CHN} functional groups are also used for further hydrophilization by auxiliary raw materials that facilitate modification, as will be described in detail in the eighth embodiment.

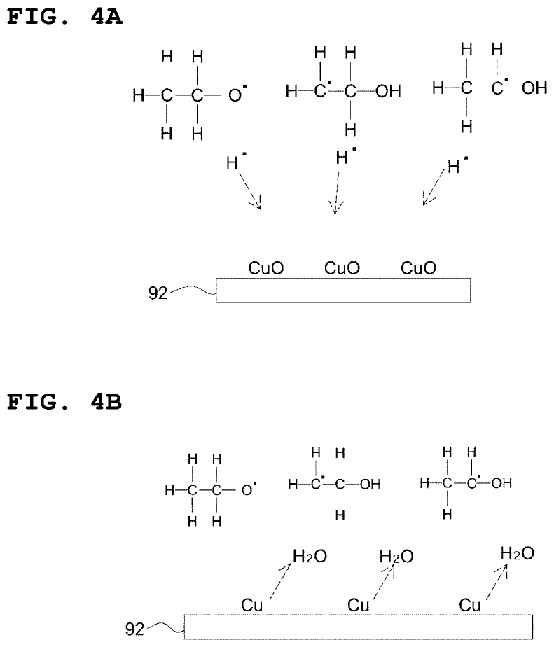

Next, with reference to FIGS. 4A and 4B, the surface modification will be described when the workpiece 9 is a metal oxide layer formed on the surface of a printed wiring board. FIG. 4A is a cross-sectional view of a metal oxide film 92 (in this case, copper oxide), schematically illustrating a state in which the metal oxide film 92 is just about to be subjected to surface modification. FIG. 4B is a cross-sectional view of the metal oxide layer 92 schematically illustrating a state in which the metal oxide layer 92 in FIG. 4A has been subjected to surface modification. FIGS. 4A and 4B are illustrated in a manner that it is easily understood that the surface of the metal oxide layer 92 is CuO.

As shown in FIG. 4A, there exist {CHO} radicals generated from ethanol molecules and hydrogen radicals in the vicinity of the surface of the metal oxide layer 92. The hydrogen radicals break the bonds between the metal atoms (in this case, Cu) constituting the metal oxide layer 92 and oxygen atoms. The hydrogen radicals combine with the isolated oxygen atoms to form water molecules. This reaction removes the oxygen atoms from the surface of the metal oxide layer 92. Accordingly, when the workpiece 9 is a metal oxide film, the metal oxide film is effectively reduced by supplying radicals formed by activating an organic compound containing oxygen atoms. The isolated {CHO} radicals combine with other {CHO} radicals to generate the alteration products of the raw material gas. Although not shown in the figure, the metal oxide layer can be reduced even when {CHN} radicals are used.

### Raw Material Gas

In the above, the case where the raw material gas G2 is ethanol is described as an example; however, the raw material gas G2 other than ethanol can also be used for the above-mentioned surface modification. Among organic compounds containing oxygen atoms, it is particularly desirable that the raw material gas G2 is an organic compound containing at least one of hydroxy group, carbonyl group, and ether bond. Furthermore, alcohols, ketones, aldehydes, and carboxylic acids are suitably used as the raw material gas G2. Alcohols contain hydroxy groups and exhibit strong hydrophilicity on the surface of fluororesin. Ketones and aldehydes contain carbonyl groups and exhibit strong hydrophilicity on the surface of fluororesin. Carboxylic acids contain hydroxy groups and carbonyl groups, i.e., carboxy groups, thus exhibiting strong hydrophilicity on the surface of fluororesin. Alcohols, ketones, aldehydes, and carboxylic acids exhibit a strong reducing power even when the workpiece 9 is a metal oxide layer. It is preferable that the organic compound containing nitrogen atoms contain at least one of an amino group, imino group, and cyano group, and more preferable that the organic compound contain at least one selected from the group consisting of amines having a carbon number of 4 or less and nitriles having a carbon number of 4 or less. For example, the organic compound may be methylamine, ethylamine, or acetonitrile.

Among alcohols, alcohols having a carbon number of 10 or less are preferable as the raw material gas G2, and, in particular, alcohols having a carbon number of 4 or less are more preferable, considering safety for human bodies, simplicity of handling, ease of availability, and economical efficiency. Among ketones, ketones having a carbon number of 10 or less are preferable as the raw material gas G2. Alcohols having a carbon number of 2 or more are further preferable because methanol, which has a carbon number of one, can have harmful effects on human bodies. Among ketones, acetone is preferable.

### Concentration Control of Raw Material Gas

As described above, when the design of a photo treatment device using an organic compound containing oxygen atoms in the raw material gas G2 is considered, it is important to control the concentration of the raw material gas G2 in the mixed gas. If the concentration of the raw material gas G2 is too low, fewer organic compounds react with the surface of the workpiece 9, lowering treatment efficiency. If the concentration of the raw material gas G2 is too high, it is difficult for ultraviolet light to reach the surface of the workpiece 9, which inhibits the generation of radicals on the surface of the workpiece 9, thereby lowering treatment efficiency. Furthermore, a high concentration of the raw material gas G2 in the mixed gas may cause abnormal combustion such as explosions. From the viewpoint of preventing abnormal combustion, concentration control is also necessary.

The preferred concentration range of the raw material gas G2 varies depending on the raw material gas species. One of the reasons for this is that the absorption rate of ultraviolet light differs depending on the raw material gas species. For example, when ethanol, which has a relatively small absorption rate of ultraviolet light, is used as the raw material gas G2, problems do not occur even in a high concentration, and in fact, more radicals are generated, thereby increasing the treatment efficiency. In contrast, when diethyl ether, which has a relatively high absorption rate of ultraviolet light, is used as the raw material gas G2, the treatment efficiency is decreased in a high concentration. Furthermore, diethyl ether has a lower concentration for the occurrence of abnormal combustion than ethanol and needs to be at lower concentrations than ethanol for safe use.

The gas generator 5 will be described with reference to FIG. 2B. The gas generator 5 in the present embodiment generates the mixed gas (G1+G2) by the bubbling method such that the partial pressure of the raw material gas G2 is in the desired range. The gas generator 5 includes a container 55 that stores an organic solvent 51, and a carrier gas supply pipe 52 through which the carrier gas G1 is supplied to the organic solvent 51 in the container 55.

The organic solvent 51 is, for example, a liquid containing an organic compound containing oxygen atoms (e.g., ethanol), and the carrier gas G1 is blown into the liquid to volatilize the liquid and extract the organic compound containing oxygen atoms as a gas. Accordingly, the mixed gas (G1+G2) is obtained from the raw material gas G2 containing the carrier gas G1 and the organic compound containing oxygen atoms. The gas generator 5 can regulate the mixing ratio of the raw material gas G2 to the carrier gas G1 by regulating the concentration or liquid volume of the organic solvent 51.

The carrier gas supply pipe 52 is provided with a flow regulating valve 54 and a flow meter 53. The gas generator 5 can also regulate the mixing ratio of the raw material gas G2 to the carrier gas G1 by regulating the supply volume of the carrier gas G1 using the flow regulating valve 54 while observing the flow meter 53.

The photo treatment device 10 of the present embodiment includes a raw material gas concentration detector 6 that detects the concentration of the raw material gas G2 in the mixed gas (G1+G2). Based on the detection results of the raw material gas concentration detector 6, the concentration or liquid volume of the organic solvent 51, the supply volume of the carrier gas G1 or the like can be regulated. The raw material gas concentration detector 6 is not an essential component of the photo treatment device 10. The raw material gas concentration can be detected, for example, by attaching a raw material gas concentration detector to the photo treatment device only when the detection is desired.

The raw material gas concentration detector 6 can be disposed anywhere in the mixed gas supply pipe 56 that connects the container 55 storing the organic solvent 51 to the gas supply port 2, in the chamber 1, or in the gas exhaust pipe (not shown in FIG. 2B) connected to the gas discharge port 4. However, it is more preferable that the raw material gas concentration detector 6 is connected to the mixed gas supply pipe 56. This is because the sensor of the raw material gas concentration detector 6 may exhibit a stronger sensitivity to the alteration products of the raw material gas that have been generated by the irradiation of ultraviolet light than to the raw material gas G2. Since there are no alteration products of the raw material gas in the mixed gas supply pipe 56, which is located upstream of the chamber 1, connecting the raw material gas concentration detector 6 to the mixed gas supply pipe 56 suppresses the false detection of the sensor caused by the alteration products of raw material gas.

When controlling the concentration, operators may manually regulate the concentration or liquid volume of the organic solvent 51 or the supply volume of the carrier gas G1, or the photo treatment device 10 may include a controller to allow the photo treatment device 10 to automatically control the concentration. For example, the concentration of raw material gas may be regularly detected by the raw material gas concentration detector 6, and based on the detection results, the controller may be given feedback control of the concentration or liquid volume of the organic solvent 51 or the supply volume of the carrier gas G1.

### Chamber

With reference to FIGS. 2A and 2B, the chamber 1 will be described in detail. In the present embodiment, the chamber 1 includes the table 11 on which the workpiece 9 is placed and that is capable of lifting and lowering by a lifting mechanism 16. The lifting mechanism 16 allows the table 11 to lower (state shown in FIG. 2A) to load and unload the workpiece 9. The lifting mechanism 16 allows the table 11 to lift to form a treatment space 19 (state shown in FIG. 2B), and the workpiece 9 is irradiated with ultraviolet light.

As described above, the chamber 1 includes the gas supply port 2 in its enclosure through which the mixed gas (G1+G2) is supplied inside, and the gas discharge port 4 through which the gas G3 inside the chamber is discharged. The gas discharge port 4 is located at a position facing the gas supply port 2. The table 11 includes side walls 13 surrounding the table 11, a gas jetting nozzle 17, and a gas recovery nozzle 18. The gas jetting nozzle 17 is disposed, among the side walls 13, at a position near the gas supply port 2. The gas recovery nozzle 18 is disposed, among the side walls 13, at a position near the gas discharge port 4 and at a position facing the gas jetting nozzle 17.

The gas jetting nozzle 17 is a flexible tube and is connected to the gas supply port 2 of the chamber 1 for allowing ventilation. The gas recovery nozzle 18 is a flexible tube and is connected to the gas discharge port 4 of the chamber 1 for allowing ventilation. Providing the gas jetting nozzle 17 and the gas recovery nozzle 18 suppresses changes in the flow of the mixed gas (G1+G2) even if the height of the lifting mechanism 16 changes.

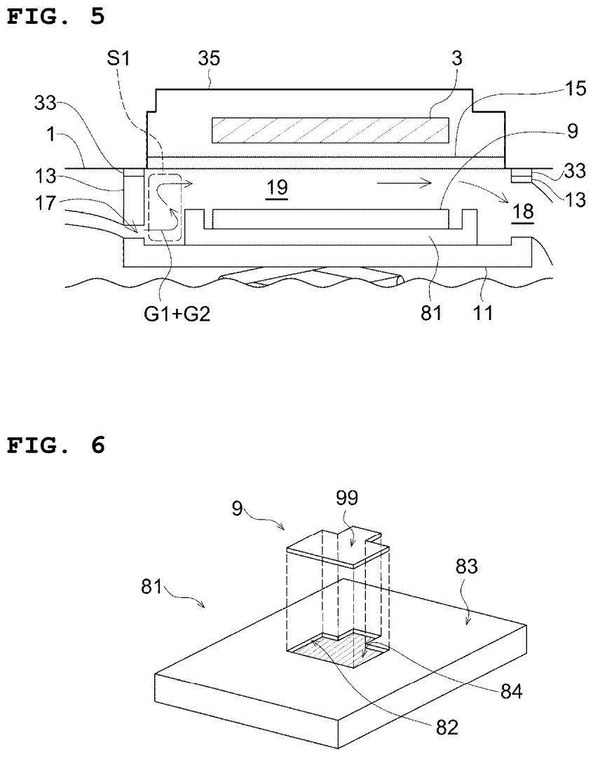

FIG. 5 is a partially enlarged view of the area around the treatment space 19 in FIG. 2B. The treatment space 19 will be described below. In the present embodiment, when the table 11 is lifted, a seal material 33 located on the upper part of the side walls 13 surrounding the table 11 brings into contact with a ceiling in the inner side of the chamber 1. This forms the treatment space 19 in the chamber 1 that is smaller than the internal space of the enclosure of the chamber 1. The treatment space 19 is a space enclosed by the table 11 (including the side walls 13) and the ceiling in the inner side of the chamber 1 (including the portion of the enclosure 15 located between the light source 3 and the chamber 1). Forming the enclosed and small treatment space 19 in the chamber 1 decreases the supply volume of mixed gas.

The flow of gas in the treatment space 19 will be described below. The mixed gas (G1+G2) jetted from the gas jetting nozzle 17 flows into a buffer space S1 that is located between the auxiliary plate 81 (details of the auxiliary plate 81 are described below) and the side wall 13 where the gas jetting nozzle 17 is provided. The buffer space S1 refers to the space where the mixed gas (G1+G2) jetted from the gas jetting nozzle 17 is not directly supplied to the surface of the workpiece 9, but is retained by colliding with the wall face, plate, and the like.

In the buffer space S1 of the present embodiment, the mixed gas (G1+G2) collides with the outer side face of the auxiliary plate 81 and the side wall 13 to lower the flow rate of the mixed gas (G1+G2). For this purpose, the height of the gas jetting nozzle 17 provided in the side wall is preferably lower than the surface of the auxiliary plate 81.

The target with which the mixed gas (G1+G2) collides is not limited to the outer side face of the auxiliary plate 81 and the side wall 13 as described above, but can also be configured such that the mixed gas (G1+G2) collides with the inner wall face of the space where the workpiece 9 is placed (for example, the inner wall face of the chamber 1). In the case where the workpiece 9 has a large thickness, the mixed gas (G1+G2) may collide with the outer side face of the workpiece 9.

A baffle plate may be disposed at a position spaced apart from and facing the jetting port of the gas jetting nozzle 17. The baffle plate is used to change the direction in which the mixed gas (G1+G2) is jetted so as to collide with the wall faces, sides, and the like or to facilitate retention. Placing the baffle plate provides the advantage of suppressing a localized and unbalanced jetting of the mixed gas (G1+G2) and promoting a uniformly dispersed jetting.

The mixed gas (G1+G2) that has passed through the buffer space S1 flows upward to the workpiece 9. Providing the buffer space S1 allows the mixed gas (G1+G2) to form a flow moving toward the gas recovery nozzle 18 above the workpiece 9 in a state of laminar flow with a restrained flow rate. This improves the uniformity of the concentration of the mixed gas (G1+G2) on the workpiece 9.

The baffle plate for the mixed gas (G1+G2) may be disposed in the gas jetting nozzle 17 or in the treatment space 19 as well as in the buffer space S1, so as to make the mixed gas (G1+G2) form a laminar flow with a restrained flow rate above the workpiece 9.

The caliber of the gas recovery nozzle 18 is larger than that of the gas jetting nozzle 17. Alternatively, the cross-sectional area of the gas recovery nozzle 18 is larger than that of the gas jetting nozzle 17. This enables the gas exhaust capacity to be larger than the gas supply capacity, thereby resulting in suppressing the turbulence of the mixed gas (G1+G2) in the treatment space 19 associated with an insufficient exhaust and the gas leakage from anywhere other than the gas recovery nozzle 18 to the outside of the treatment space 19 associated with an increase in the pressure in the treatment space 19.

With reference to FIG. 2B, similarly, the caliber of the gas discharge port 4 connected to the gas recovery nozzle 18 can also be larger than the caliber of the gas supply port 2 connected to the gas jetting nozzle 17. This allows the gas exhaust capacity to be larger than the gas supply capacity, thereby resulting in suppressing the turbulence of the mixed gas in the chamber 1 associated with an insufficient exhaust and the gas leakage from anywhere other than the gas discharge port 4 to the outside of the space in the chamber associated with an increase in the pressure in the space inside the chamber 1.

In the present embodiment, one gas jetting nozzle 17 and one gas recovery nozzle 18 are provided. However, either the plurality of gas jetting nozzles 17 or the plurality of gas recovery nozzles 18 may be disposed. The number of the gas jetting nozzles 17 can be different from that of the gas recovery nozzles 18. When either the plurality of gas jetting nozzles 17 or the plurality of gas recovery nozzles 18 are provided, the total cross-sectional area of the gas recovery nozzles 18 may be larger than that of the gas jetting nozzles 17. This enables the gas exhaust capacity to be larger than the gas supply capacity.

The auxiliary plate 81 will be described with reference to FIG. 6. In the present embodiment, the auxiliary plate 81 that surrounds the workpiece 9 is provided. The auxiliary plate 81 has an inner side face 82 that is in contact with the outer periphery of the workpiece 9 when the workpiece 9 is fitted therein, and a surface 83 that is to be substantially flush with a surface to be treated 99 of the workpiece 9 when the workpiece 9 is fitted therein. Using the auxiliary plate 81 makes it possible to suppress the turbulence of the mixed gas (G1+G2) when the supplied mixed gas (G1+G2) flows above the surface 83 of the auxiliary plate 81 and the surface to be treated 99, promoting uniform treatment of the surface to be treated 99.

The term “substantially flush” means that the step between the surface 83 of the auxiliary plate 81 and the surface to be treated 99 does not create turbulence in the mixed gas (G1+G2) that prevents uniform treatment. For example, it is preferable that the step between the surface 83 of the auxiliary plate 81 and the surface to be treated 99 is 5 mm or less, and more preferable that the step is 1 mm or less.

The auxiliary plate 81 of the present embodiment has a recess 84 (the area hatched with a shaded line in FIG. 6) in accordance with the shape of the workpiece 9. Accordingly, the auxiliary plate 81 can be used as a carrier plate that can transport the workpiece 9 by placing it in the recess 84. The carrier plate protects the workpiece 9 from contact scratches during transportation or facilitates the transportation of the workpiece 9 even if the workpiece 9 has a shape that is difficult to hold. When the auxiliary plate is not used as a carrier plate, a through-hole may be formed in place of the recess 84. The auxiliary plate 81 may be integrated with the table 11 without being used as a carrier plate. Note that the shape of the workpiece 9 shown in FIG. 6 is an example; however, the shape of the workpiece 9 is not limited to this shape.

The auxiliary plate 81 in the present embodiment is a member that surrounds all of the surroundings of the workpiece 9. However, the shape of the auxiliary plate 81 is not limited to this. The auxiliary plate 81 may be in contact with a part of sides of the workpiece 9 when the workpiece 9 is fitted therein or may have a gap between it and the workpiece 9. The auxiliary plate 81 may be divided into a plurality of parts.

As a Variation Example, the chamber 1 may not necessarily form the treatment space 19 that is smaller than the internal space of the enclosure of the chamber 1. In that case, the table 11 may not necessarily include the side walls 13 surrounding the table 11, the gas jetting nozzle 17 and the gas recovery nozzle 18. In addition, the lifting mechanism that brings the table 11 into contact with the ceiling of the chamber 1 is not an essential component. Furthermore, the chamber 1 may not necessarily include the table 11. In the case where the chamber 1 does not include the table 11, the workpiece 9 may be placed so as to be in contact with the floor face, wall face, or ceiling face of the chamber 1.

### Light Source

As described above, in the present embodiment, the light source 3 is disposed inside the light source chamber 35. The surroundings of the light source 3 and the inside of the light source chamber 35 are filled with an inert gas, such as nitrogen gas, which transmits ultraviolet light. This allows ultraviolet light to be transmitted through the atmospheric gas located between the light source 3 and the chamber 1. Hence, the ultraviolet light Ll is less likely to be attenuated in the light source chamber 35. The atmospheric gas is supplied and discharged from a supply port (not shown) and a discharge port (not shown) provided in the walls or ceiling of the light source chamber 35, respectively.

Typically, applying a high voltage causes an electrical discharge phenomenon to occur in the light source 3. Hence, there is a risk that the light source 3 may become a starting point of combustion, i.e., a source of fire. Placing the light source 3 outside the chamber 1 allows the light source 3 to be away from the raw material gas G2, providing effects of further reducing the risk of abnormal combustion of the raw material gas G2. This also prevents the alteration products of the raw material gas G2 from adhering to the surface of the light source 3, thereby providing effects of preventing a decrease in the illuminance of the light source 3. Furthermore, the chamber 1 can be made smaller, and maintenance, inspection, or replacement of the light source 3 can be simplified.

With regard to a spacing between the light source 3 and the workpiece 9, the workpiece 9 is placed not to be too far from the light source 3 such that the ultraviolet light L1 generates radicals in the vicinity of the workpiece 9 because the ultraviolet light L1 is absorbed by the mixed gas (G1+G2). Also, the workpiece 9 is placed not to be too close to the light source 3 because the amount of the raw material gas G2 that absorbs the ultraviolet light L1 decreases if the workpiece 9 is placed too close to the light source 3. In other words, the workpiece 9 is made to be separated from the light source 3 to the extent that the ultraviolet light L1 generates radicals and the generated radicals are in contact with the surface of the workpiece 9. The spacing between the workpiece 9 and the light source 3 is preferably 0.2 mm or more and 20 mm or less, more preferably from 0.5 mm or more and 5 mm or less.

Apart from the above-mentioned lifting mechanism 16, a lifting mechanism (not shown) may be provided to adjust the spacing between the light source 3 and the workpiece 9. Specifically, a new lifting mechanism for lifting and lowering the workpiece 9 on the table 11 may be provided to move the workpiece 9 closer to or away from the light source 3. A lifting mechanism for lifting and lowering the light source 3 may be provided to move the light source 3 closer to or away from the workpiece 9. When the side walls of the table 11 are not in contact with the ceiling of the chamber 1, the above-mentioned lifting mechanism 16 may be used to adjust the spacing between the light source 3 and the workpiece 9.

### How to use the Photo Treatment Device

An example of how to use the photo treatment device 10 will be described. First, the lifting mechanism 16 in the chamber 1 is used to lower the table 11. Then, the workpiece 9 is loaded into the chamber 1 from a loading exit for the workpiece 9 (not shown) provided in the chamber 1, and the workpiece 9 is placed on the table 11. This state is illustrated in FIG. 2A.

Next, the lifting mechanism 16 is used to lift the table 11 to form the treatment space 19. Then, in the gas generator 5, the carrier gas G1 is supplied into the organic solvent 51 to bubble, generating the mixed gas (G1+G2) of the raw material gas G2 and the carrier gas G1. The mixed gas (G1+G2) is introduced from the gas supply port 2 connected to the mixed gas supply pipe 56 to replace (purge) the inside of the chamber 1 with the mixed gas (G1+G2). The atmosphere (air) originally present in the treatment space 19 is discharged from the gas discharge port 4 through the gas recovery nozzle 18.

After the chamber 1 is filled with the mixed gas (G1+G2), the light source 3 is made to emit to excite the raw material gas G2 in the mixed gas (G1+G2), generating {CHO} radicals and hydrogen radicals. At least one of the hydrogen radicals and the {CHO} radicals acts on the workpiece 9 to perform the surface modification of the workpiece 9. The state in which the surface modification treatment is in progress is shown in FIG. 2B.

In the present embodiment, even if the workpiece 9 has a large surface area, the surface can be modified in a short time. In addition, since radicals are generated in the vicinity of the workpiece 9, the utilization efficiency of the generated radicals is high.

During the treatment, the ultraviolet light Ll may be emitted while the mixed gas (G1+G2) is continuously supplied to the chamber 1, or the ultraviolet light L1 may be emitted in a state of stopping the supply of the mixed gas (G1+G2) by shutting off the gas supply port 2 with a valve or the like.

### Second Embodiment

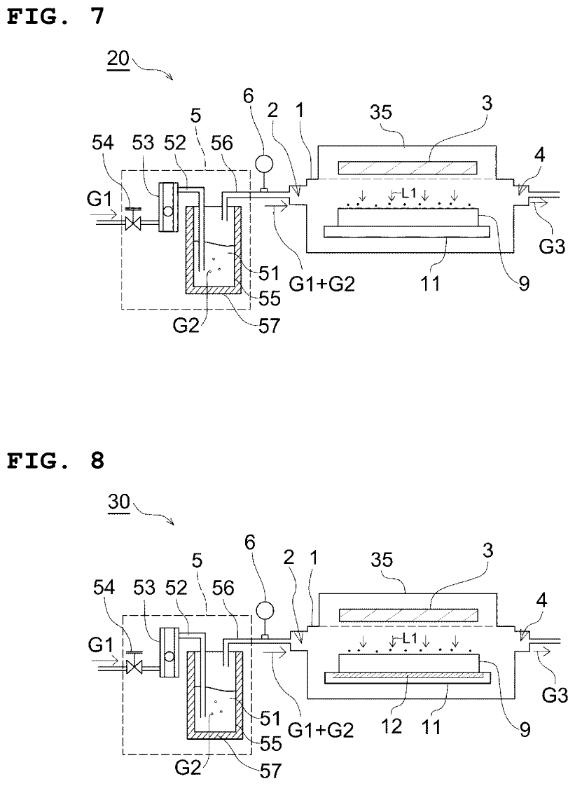

With reference to FIG. 7, the photo treatment device of a second embodiment will be described. Matters other than those described below can be implemented similarly as in the first embodiment. The same applies to the third embodiment and subsequent embodiments. In FIG. 7 and subsequent figures, unless otherwise mentioned, the shape of enclosure of the chamber 1, the position of the light source 3, and the structure inside the chamber 1 are shown in a simplified fashion. The lifting mechanism of the table 11, the side walls provided in the table 11, the gas jetting nozzle and the gas recovery nozzle, the auxiliary plate, and the like are omitted from the figure.

In the photo treatment device 20 shown in FIG. 7, the gas generator 5 includes a heater 57 (indicated with the hatched area surrounding the container 55) that heats the container 55. The heater 57 heats the container 55 to raise the temperature of the organic solvent 51. As the organic solvent 51 rises in temperature, the mixed gas (G1+G2) rises in temperature, increasing the saturated vapor pressure of the mixed gas (G1+G2). This results in expanding the numerical range of possible mixing ratios of the raw material gas G2 to the carrier gas G1. Moreover, since the mixed gas (G1+G2) is supplied at high temperatures, chemical reactions on the surface of the workpiece can be accelerated.

The mixed gas supply pipe 56 may be covered with an insulating material to prevent the mixed gas (G1+G2) from being cooled by the mixed gas supply pipe 56. The mixed gas supply pipe 56 may also be heated by a heater. Furthermore, the temperature of the mixed gas (G1+G2) can be increased by using another heater to raise the temperature of the carrier gas G1 supplied to the gas generator 5.

### Third Embodiment

With reference to FIG. 8, the photo treatment device of a third embodiment will be described. In the photo treatment device 30, the temperature of the workpiece 9 is regulated (heated or cooled) by a temperature regulator 12 provided in the table 11. The temperature regulator 12 of the present embodiment is a pipe through which temperature-regulated fluid (heating fluid or cooling fluid) is passed. The pipe is embedded in the table 11. However, the temperature of the workpiece 9 can also be adjusted by electric energy using an electric heating wire, a thermoelectric device, or the like. It is also possible to heat the workpiece 9 using light energy such as an infrared light source.

Depending on the type of the workpiece 9 and the type of the raw material gas G2, an increase in the temperature of the workpiece 9 may increase the reaction rate on the surface of the workpiece 9. Alternatively, depending on the type of the workpiece 9 and the type of the raw material gas G2, a decrease in the temperature of the workpiece 9 may increase the molecules of organic compounds adsorbed on the surface of the workpiece 9, thereby increasing the reaction rate. In any case, adjusting the temperature of the workpiece 9 makes it possible to control the progress of chemical reactions on the surface of the workpiece 9.

### Fourth Embodiment

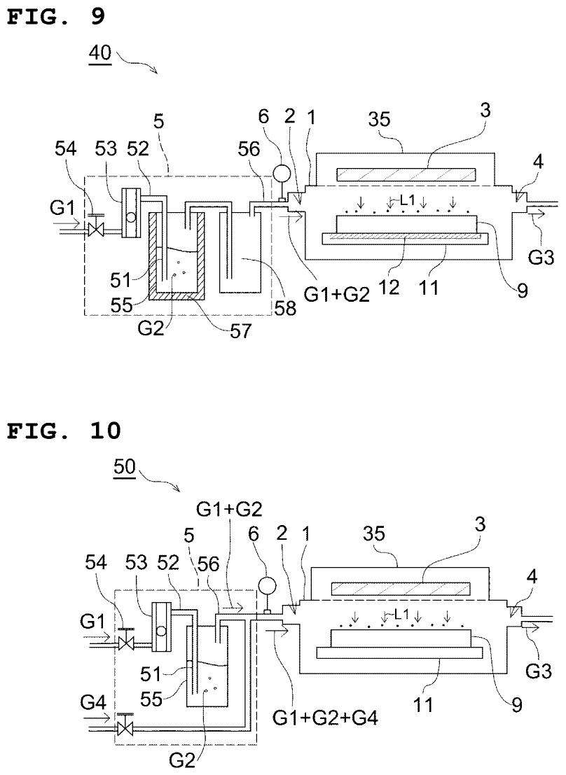

With reference to FIG. 9, the photo treatment device of a fourth embodiment will be described. The gas generator 5 of the photo treatment device 40 includes a cooler 58 that cools the mixed gas (G1+G2) between the container 55 and the gas supply port 2. Cooling the mixed gas (G1+G2) allows the saturated vapor amount of the mixed gas (G1+G2) to be lowered, condensing part of the vaporized organic solvent 51. This reduces the amount of the raw material gas G2 contained in the mixed gas (G1+G2) and regulates the mixing ratio of the raw material gas G2 to the carrier gas G1.

The photo treatment device 40 in the present embodiment includes both the heater 57 and the cooler 58; however, it may also include only the cooler 58 without the heater 57.

### Fifth Embodiment

With reference to FIG. 10, the photo treatment device of a fifth embodiment will be described. The gas generator 5 of a photo treatment device 50 generates a diluted mixed gas (G1+G2+G4) in which a dilution gas G4 is mixed with the mixed gas (G1+G2) of the carrier gas G1 and the raw material gas G2. The dilution gas G4 is, for example, an inert gas such as nitrogen gas or a noble gas (e.g., helium or argon). Mixing the dilution gas G4 makes it possible to reduce the concentration of the raw material gas G2 in the diluted mixed gas (G1+G2+G4).

Incidentally, an inert gas or the mixed gas (G1+G2) is supplied into chamber 1 to discharge the atmosphere present in the chamber 1 prior to the start of light irradiation. Discharging the atmosphere reduces the risk of combustion of the raw material gas G2 and prevents the remaining atmosphere in the chamber 1 from absorbing ultraviolet light. When the atmosphere is discharged, the supply of the mixed gas (G1+G2) can be stopped and only the dilution gas G4 can be supplied. This allows the dilution gas G4 (e.g., inert gas) to replace (purge) the atmosphere originally present in the chamber 1 prior to the start of light irradiation. Replacing the atmosphere with the dilution gas G4 instead of the mixed gas (G1+G2) makes it possible to reduce the consumption of mixed gas (G1+G2).

### Sixth Embodiment

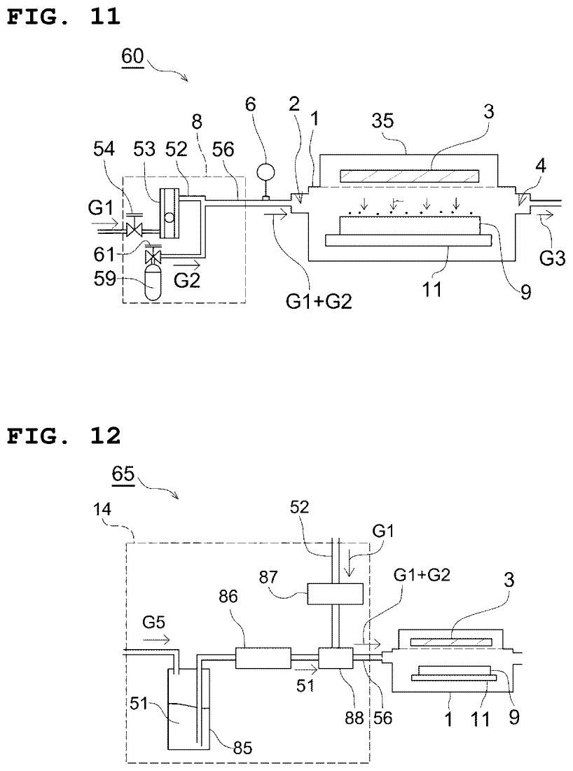

With reference to FIG. 11, the photo treatment device of a sixth embodiment will be described. A gas generator 8 of the photo treatment device 60 does not generate the mixed gas (G1+G2) by the bubbling method, instead generates the mixed gas (G1+G2) by mixing the raw material gas G2 supplied from a gas container 59 (e.g., high-pressure gas container) with the carrier gas G1. The mixing ratio of the raw material gas G2 to the carrier gas G1 can be regulated by at least one of the flow regulating valve 54 of the carrier gas G1 and a flow regulating valve 61 of the gas container 59.

### Seventh Embodiment

With reference to FIG. 12, the photo treatment device of a seventh embodiment will be described. A gas generator 14 of a photo treatment device 65 generates the raw material gas G2 by the direct vaporization method. The gas generator 14 includes a vaporizer 88 that introduces and vaporizes the liquid organic solvent 51 containing an organic compound such as ethanol, the carrier gas supply pipe 52 connected to the vaporizer 88 and that supplies the carrier gas G1 thereto, and the mixed gas supply pipe 56 that delivers the resulting mixed gas (G1+G2) to the chamber 1. The mixed gas (G1+G2) of the carrier gas G1 and the raw material gas G2 is generated by supplying the carrier gas G1 with the raw material gas G2, which is generated by vaporizing the organic solvent 51 instantaneously in the vaporizer 88.

The gas generator 14 further includes a mass flow controller (86, 87). The mass flow controller 86 regulates the liquid volume of the organic solvent 51 supplied to the vaporizer 88. The mass flow controller 87 regulates the gas volume of the carrier gas supplied to the vaporizer 88. The mass flow controllers (86, 87) are controlled by a controller (not shown). Using the mass flow controllers (86, 87) enables the concentration of the raw material gas G2 and the carrier gas G1 to be more precisely controlled. As shown in FIG. 12, the organic solvent 51 can be discharged from the container 85 by feeding a pressurized gas G5 into the container 85 in which the organic solvent 51 is contained.

### Eighth Embodiment

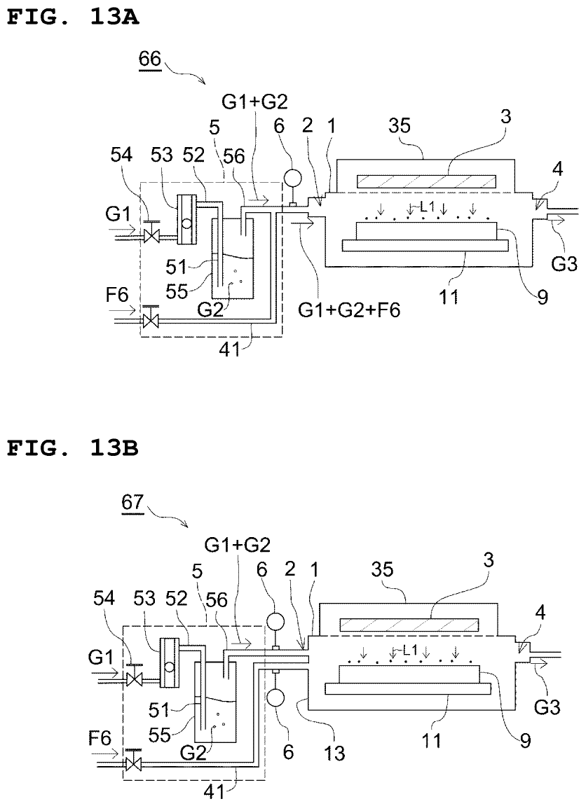

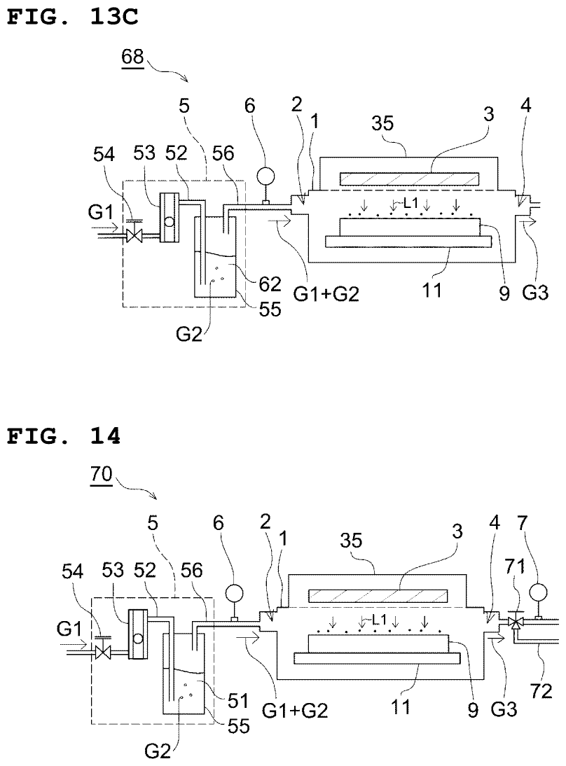

With reference to FIG. 13A, the photo treatment device of an eighth embodiment will be described. A photo treatment device 66 includes a supplementary fluid supply pipe 41. The supplementary fluid supply pipe 41 supplies the chamber 1 with a fluid F6 containing an auxiliary raw material that facilitates the modification of the workpiece 9. In FIG. 13A, the supplementary fluid supply pipe 41 is connected to the mixed gas supply pipe 56 for allowing ventilation, thereby mixing the fluid F6 with the raw material gas.

The auxiliary raw material that facilitates the modification of the workpiece 9 will be described. One example of such auxiliary raw material is water vapor or atomized water. The irradiation of water vapor or atomized water with the above-mentioned ultraviolet light generates OH radicals and hydrogen radicals from water molecules. As shown in FIGS. 3B and 3D, many hydrocarbon groups are added to the surface of the fluororesin 91. The OH radicals and hydrogen radicals generated from the water molecules break the C—H bonds in the added hydrocarbon groups, pull out the hydrogen atoms, and allow the OH radicals to bind at the portions where the hydrogen atoms have been pulled out. This increases the number of OH groups on the surface of fluororesin, further proceeding hydrophilization on the surface of fluororesin. Accordingly, the auxiliary raw material serves to facilitate the modification of the workpiece due to the additional treatment.

Fluororesin is a porous material. When a material to be treated is fluororesin, fluorine on the surface of fluororesin is removed by surface modification thereof caused by the raw material gas G2 (gas containing an organic compound containing oxygen atoms or nitrogen atoms), water molecules can penetrate the fluororesin. When water that has penetrated the interior thereof is radicalized by ultraviolet light inside the fluororesin, hydrophilization of the fluororesin also proceeds inside the fluororesin.

Water vapor or atomized water can be obtained, for example, by bubbling a container filled with water with an inert gas such as nitrogen gas.

Oxygen gas may also be used as an auxiliary raw material gas. The irradiation of oxygen gas with the above-mentioned ultraviolet light generates oxygen radicals. Part of oxygen radicals combines with other oxygen molecules to generate ozone (O₃). As shown in FIGS. 3B and 3D, many hydrocarbon groups are added to the surface of the fluororesin 91. Oxygen radicals break the C—H bonds contained in the hydrocarbon groups on the surface, pull out hydrogen atoms, and allow oxygen radicals or ozone to bind. Accordingly, the modification treatment that allows the surface of fluororesin to oxidize is performed. In addition, the oxygen-based functional group generated by the modification treatment has polarity, thereby further proceeding hydrophilization on the surface of fluororesin.

However, as described above, if the auxiliary raw material is oxygen gas, the risk of combustion may increase when mixed with the raw material gas G2. There are two methods for decreasing the risk of combustion.

The first method is to avoid mixing the raw material gas G2 with oxygen gas in the first place. After the modification treatment with the raw material gas G2 is completed, the modification treatment with oxygen gas is performed.

FIG. 13B is a first Variation Example of the photo treatment device of the eighth embodiment. In FIG. 13B, the supplementary fluid supply pipe 41 is directly connected to the chamber 1 for allowing ventilation at a position different from a position where the mixed gas supply pipe 56 is connected to the chamber 1 for allowing ventilation. Oxygen gas is not supplied to the chamber 1 while the mixed gas (G1+G2) is supplied through the supplementary fluid supply pipe 41. This avoids mixing the raw material gas G2 with oxygen gas.

In FIG. 13B, the supplementary fluid supply pipe 41 is connected to the same side wall of the chamber 1 as that to which the mixed gas supply pipe 56 is connected; however, the supplementary fluid supply pipe 41 may be disposed in a side wall, floor or ceiling of the chamber 1 different from those in which the mixed gas supply pipe 56 is disposed.

Furthermore, no mixed gas of the raw material gas G2 and the oxygen gas is also generated when the modification treatment with oxygen gas using the auxiliary raw material is performed in a second chamber partitioned from the chamber 1 where the modification treatment with the raw material gas G2 is performed. In this case, the workpiece is transported to the second chamber after the modification treatment with the raw material gas G2 has been treated.

The second method is a method in which at least one of the organic compound and the oxygen gas is made at a concentration below a combustion limit value when the organic compound and the oxygen gas are supplied simultaneously. This method is particularly suitable when the organic compound and oxygen gas need to be mixed.

The combustion limit value of an organic compound refers to the lowest concentration of an organic compound at which combustion can occur in the case where the organic compound is mixed with oxygen gas when some thermal energy or the like is applied. The combustion limit value of oxygen gas refers to the lowest concentration of oxygen gas at which combustion can occur in the case of being mixed with an organic compound when some thermal energy or other is applied. When the concentration of either an organic compound or oxygen gas is below the combustion limit value, combustion will not occur even in the case where an organic compound is mixed with oxygen gas and some thermal energy or the like is applied to the mixed gas. To reduce the concentration of an organic compound or oxygen gas, an inert gas can be included in the mixed gas (G1+G2) or an inert gas can be included in the oxygen gas. The method of including an inert gas in the oxygen gas includes the use of air.

The combustion limit value of oxygen gas for ethanol at room temperature and atmospheric pressure is 10.5%. In the case where ethanol gas is present at room temperature and atmospheric pressure in the mixed gas of the raw material gas and oxygen gas, setting the oxygen concentration in the mixed gas less than 10.5% suppresses combustion regardless of the ethanol concentration. Hence, it is desirable that an inert gas such as nitrogen gas is included in the raw material gas or oxygen gas before the mixing so as to make the oxygen concentration in the mixed gas less than 10.5%. The oxygen concentration in the mixed gas is preferably 20% or less, more preferably 10% or less, and further preferably 5% or less.

The method of making the concentration of at least one of an organic compound or oxygen gas below the combustion limit value as described above is one example. Other methods include reducing the pressure or temperature of an organic compound and oxygen gas, for example.

The auxiliary raw material need not be water or oxygen gas. The auxiliary raw material can be selected depending on the purpose of modification, the type of material to be treated, and the type of functional group attached to the surface of the material to be treated by an organic compound containing oxygen atoms or nitrogen atoms. An organic compound different from the raw material gas may be used as the auxiliary raw material. When the purpose of the modification is the reduction treatment of the surface of the workpiece, the auxiliary raw material may be selected from materials having reducing power.

FIG. 13C is a second Variation Example of the photo treatment device of the eighth embodiment. The container 55 is filled with ethanol to which water, which is the auxiliary raw material, has been added, i.e., an aqueous ethanol solution 62. Vaporizing the aqueous ethanol solution 62 makes it possible to simultaneously produce both of ethanol gas (an organic compound having oxygen atoms) and water vapor or atomized water (an auxiliary raw material that facilitates the modification of the workpiece through radicalization).

Upon vaporization, bubbling the aqueous ethanol solution 62 with oxygen gas or a gas containing oxygen gas (such as air) makes it possible to obtain a fluid containing ethanol gas, water vapor or atomized water, and oxygen gas. Selecting an inert gas as the gas for bubbling upon vaporization can suppress abnormal combustion.

### Ninth Embodiment

With reference to FIG. 14, the photo treatment device of a ninth embodiment will be described. A photo treatment device 70 includes an oxygen concentration detector 7 that detects the oxygen concentration contained in the gas discharged from the chamber 1. In the case where the atmosphere present in the chamber 1 is discharged, when the oxygen concentration detector 7 fails to detect the oxygen concentration or detects a trace amount thereof, it is confirmed that the inside of the chamber 1 is replaced with the carrier gas G1, the dilution gas G4 or the mixed gas (G1+G2).

A switching valve 71 is provided between the chamber 1 and the oxygen concentration detector 7. When the oxygen concentration detector 7 is unused, the switching valve 71 may be used to allow the gas discharged from the chamber 1 to flow into a channel 72. This reduces the contamination of the oxygen concentration detector 7 caused by reaction products that has been generated in the chamber 1.

### Tenth Embodiment

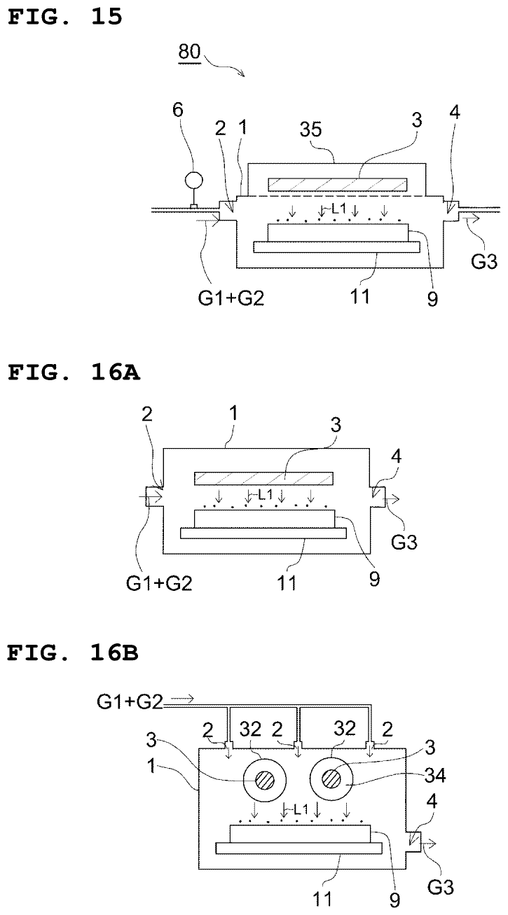

With reference to FIG. 15, the photo treatment device of a tenth embodiment will be described. A photo treatment device 80 includes a chamber 1 including the gas supply port 2 that supplies the mixed gas (G1+G2) and capable of placing the workpiece 9 thereinside, the light source 3, and the raw material gas concentration detector 6 that detects the concentration of the raw material gas G2 in the mixed gas (G1+G2). In the present embodiment, the photo treatment device 80 does not include the gas generator 5 and allows the mixed gas (G1+G2) that has been mixed in a predetermined mixing ratio to be introduced from outside the photo treatment device 80.

The raw material gas concentration detector 6 is used to detect the concentration of the raw material gas G2 in the supplied mixed gas (G1+G2). If the concentration of the raw material gas G2 is out of the desired range, the mixing ratio of the raw material gas G2 to the carrier gas G1 in the supplied mixed gas is regulated. The inflow of the mixed gas (G1+G2) may be automatically stopped, or the irradiation of light may be automatically stopped. Furthermore, the controller in the photo treatment device 80 may issue an error signal.

Each embodiment has been described above. However, the present invention is not limited in any way to the above-mentioned embodiments, and various modifications or improvements may be made to the above embodiments to the extent from which the scope of the present invention is not departed. The above embodiments may also be combined.

Here is an example of modification or improvement of the photo treatment device. A variety of variation examples can be considered in the structure and arrangement of the chamber 1 and the light source 3 in the photo treatment device. With reference to FIGS. 16A and 16B, such variation examples of the photo treatment device will be described. FIGS. 16A and 16B are each a schematic view of the photo treatment device illustrating only an area around the chamber 1 and the light source 3.

In FIG. 16A, the light source 3 is disposed in the chamber 1. Since the photo treatment device does not include the light source chamber described above, the structure of the photo treatment device is simplified. Furthermore, the spacing between the light source 3 and the workpiece 9 can be smaller than that when the light source 3 is disposed outside the chamber 1.

In FIG. 16B, the two light sources 3 are arranged such that the longitudinal direction of each light source 3 is from the front to the back of the drawing. Both of the light sources 3 are housed in a cylinder body 32 extending from the front to the back of the drawing. Of the cylinder body 32, at least the part facing the workpiece 9 is made of a material that transmits the ultraviolet light L1 (e.g., quartz glass, calcium fluoride, etc.). A space 34 between the light source 3 and the cylinder body 32 is filled with a gas that is less likely to absorb ultraviolet light. Such gas may be supplied and discharged from a supply port (not shown) and a discharge port (not shown) provided in the cylinder body 32, respectively.

By housing the light source 3 in the cylinder body 32 and allowing the inside of the cylinder body 32 to be an inert gas atmosphere, the risk of abnormal combustion of the raw material gas G2 can be further reduced. This also prevents the alteration products of the raw material gas G2 from adhering to the surface of the light source 3, thereby preventing a decrease in the illuminance of the light source 3. Since the surroundings of the light source 3 are in an inert gas atmosphere, the ultraviolet light L1 is less likely to be absorbed by the mixed gas (G1+G2) that is located away from the workpiece 9, which is unused for the surface modification of the workpiece 9. As a result, more ultraviolet light can be radiated to the mixed gas (G1+G2) in the vicinity of the workpiece 9. Such cylinder body 32 can also be used in a form where the light source 3 is disposed in the light source chamber 35.

In FIG. 16B, the plurality of gas supply ports 2 that supply the mixed gas (G1+G2) are provided in the ceiling of the chamber 1. The location and number of the gas supply ports 2 can be set in consideration of the flow of the mixed gas (G1+G2) in order to evenly treat the workpiece 9. Similarly, the position and number of the gas discharge port 4 can be set.

### REFERENCE SIGNS LIST

1 Chamber
2 Gas supply port
3 Light source
4 Gas discharge port
5, 8, 14 Gas generator
6 Raw material gas concentration detector
7 Oxygen concentration detector
9 Workpiece
10, 20, 30, 40, 50, 60, 65, 66, 67, 68, 70, 80 Photo treatment device
11 Table
12 Temperature regulator
13 Side wall
15 Enclosure of chamber (portion located between light source and chamber)
16 Lifting mechanism
17 Gas jetting nozzle
18 Gas recovery nozzle
19 Treatment space
32 Cylinder body
33 Seal material
34 Space (between light source and cylinder body)
35 Light source chamber
41 Supplementary fluid supply pipe
51 Organic solvent
52 Carrier gas supply pipe
53 Flow meter
54, 61 Flow regulating valve
55 Container
56 Mixed gas supply pipe
57 Heater
58 Cooler
59 Gas container
71 Switching valve
72 Channel
81 Auxiliary plate
82 Inner side face (of auxiliary plate)
83 surface (of auxiliary plate)
86, 87 Mass flow controller
91 Fluororesin
92 Metal oxide layer
99 Surface to be treated (of workpiece)
F6 Fluid including auxiliary raw material
G1 Carrier gas
G2 Raw material gas
G1+G2 Mixed gas
G4 Dilution gas
G1+G2+G4 Diluted mixed gas
G5 Pressurized gas
L1 Ultraviolet light

1. A photo treatment device comprising:
a gas generator that generates a mixed gas in which a raw material gas containing an organic compound having at least one of oxygen atoms and nitrogen atoms is mixed with a carrier gas at a desired mixing ratio;
a chamber connected to the gas generator for allowing ventilation so as to enable the mixed gas to be supplied thereinside and that is capable of placing the workpiece thereinside; and
a light source that irradiates the raw material gas with ultraviolet light having intensity at least in a wavelength band of 205 nm or less,
wherein a surface of the workpiece is modified with the raw material gas that has been irradiated with the ultraviolet light.

2. The photo treatment device according to claim 1, wherein the gas generator includes a container that stores an organic solvent containing the organic compound having oxygen atoms, a carrier gas supply pipe that supplies the carrier gas to the organic solvent stored in the container, and a mixed gas supply pipe that feeds the mixed gas into the chamber; and
the mixed gas is generated by supplying the carrier gas to the organic solvent.

3. The photo treatment device according to claim 2, wherein the gas generator includes a heater that heats at least one of the container and the carrier gas.

4. The photo treatment device according to claim 1, wherein the gas generator includes a vaporizer that introduces an organic solvent containing the organic compound into a vaporization compartment to vaporize it, a carrier gas supply pipe connected to the vaporizer and that supplies the carrier gas, and a mixed gas supply pipe that delivers the mixed gas to the chamber; and
the mixed gas is generated by supplying the carrier gas to the organic solvent.

5. The photo treatment device according to claim 2, wherein the mixed gas supply pipe is connected to a dilution gas supply pipe that dilutes the mixed gas.

6. The photo treatment device according to claim 1, further comprising a cooler disposed between the gas generator and the chamber and that cools the mixed gas.

7. The photo treatment device according to claim 1, further comprising a raw material gas concentration detector that detects a concentration of the raw material gas in the mixed gas,
wherein at least one of a supply volume of the carrier gas and a supply volume of a dilution gas is regulated based on a detection result of the raw material gas concentration detector.

8. The photo treatment device according to claim 1, further comprising a supplementary fluid supply pipe that supplies a fluid containing an auxiliary raw material that facilitates a modification of the workpiece by radicalization.

9. The photo treatment device according to claim 8, wherein the supplementary fluid supply pipe is connected to the mixed gas supply pipe for allowing ventilation.

10. The photo treatment device according to claim 8, wherein the supplementary fluid supply pipe is connected to the chamber for allowing ventilation at a position different from that at which the mixed gas supply pipe is connected to the chamber for allowing ventilation.

11. The photo treatment device according to claim 2, wherein an auxiliary raw material that facilitates a modification of the workpiece is added to the organic solvent stored in the container.

12. The photo treatment device according to claim 1, further comprising:
a second chamber that is partitioned from the chamber, and capable of placing the workpiece thereinside and supplying a fluid containing an auxiliary raw material that facilitates a modification of the workpiece thereinside; and
a light source that irradiates the fluid containing the auxiliary raw material with ultraviolet light having intensity in a wavelength band of at least 205 nm or less.

13. A photo treatment device comprising:
a chamber to which a mixed gas including a raw material gas containing an organic compound having at least one of oxygen atoms and nitrogen atoms and a carrier gas is supplied and that is capable of placing a workpiece thereinside;
a light source that irradiates the raw material gas with ultraviolet light having intensity in a wavelength band of at least 205 nm or less; and
a raw material gas concentration detector that detects a concentration of the raw material gas in the mixed gas,
wherein a surface of the workpiece is modified with the raw material gas that has been irradiated with the ultraviolet light.

14. The photo treatment device according to claim 13, wherein the raw material gas concentration detector is disposed to detect the mixed gas before the mixed gas enters the chamber.

15. The photo treatment device according to claim 1, wherein the chamber includes a temperature regulator that regulates a temperature of the workpiece.

16. The photo treatment device according to claim 1, wherein the light source is located outside the chamber, and the ultraviolet light is transmitted through an enclosure of the chamber and an atmospheric gas that are located between the light source and the chamber.

17. The photo treatment device according to claim 1, wherein the light source is housed in a cylinder body, at least a part of the cylinder body allows the ultraviolet light to transmit, and the space between the light source and the cylinder body has an inert gas atmosphere.

18. The photo treatment device according to claim 1, further comprising an oxygen concentration detector that detects a concentration of oxygen contained in a gas discharged from the chamber.

19. The photo treatment device according to claim 1, wherein the chamber includes at least one gas supply port through which the mixed gas is supplied thereinside and at least one gas discharge port through which the gas inside the chamber is discharged, and a caliber of the at least one gas discharge port among the at least one gas discharge port is larger than a caliber of the at least one gas supply port among the at least one gas supply port.

20. The photo treatment device according to claim 1, wherein the chamber includes a gas supply port through which the mixed gas is supplied thereinside, a gas discharge port through which the gas inside the chamber is discharged, and a table on which the workpiece is placed and that is capable of lifting and lowering, and
the table includes at least one gas jetting nozzle connected to the gas supply port for allowing ventilation, and at least one gas recovery nozzle connected to the gas discharge port for allowing ventilation.

21. The photo treatment device according to claim 20, wherein the table has side walls surrounding the table, a seal material is disposed on an upper part of the side walls, and an enclosed treatment space is formed in the chamber by allowing the seal material to be in contact with a ceiling of the chamber.

22. The photo treatment device according to claim 20, wherein a total area of a nozzle cross-section of the gas recovery nozzle is larger than a total area of a cross-section of the gas jetting nozzle.

23. The photo treatment device according to claim 1, further comprising an auxiliary plate having an inner side face that is in contact with an outer periphery of the workpiece and a front face that is substantially flush with a surface to be treated of the workpiece.
